(19) United States
(12) Patent Application Publication
(10) Pub. No.: US 2009/0140405 A1
(43) Pub. Date: Jun. 4, 2009

(54) SEMICONDUCTOR DEVICE AND RESIN ADHESIVE USED TO MANUFACTURE THE SAME

(76) Inventors: Tetsumasa Maruo, Osaka (JP); Masanori Minamio, Osaka (JP); Kiyokazu Itoi, Kyoto (JP)

Correspondence Address: MCDERMOTT WILL & EMERY LLP, 600 13TH STREET, NW, WASHINGTON, DC, 20005-3096, US

(21) Appl. No.: 12/210,490

(22) Filed: Sep. 15, 2008

(30) Foreign Application Priority Data
Dec. 3, 2007 (JP) 2007-311926

(51) Int. Cl. H01L 23/02

(52) U.S. Cl. 257/680; 257/E23.18

(57) ABSTRACT

A semiconductor device includes: a semiconductor element; a package body having the semiconductor element bonded inside thereof and electrically connected to the semiconductor element; a lid-like member covering the semiconductor element, and bonded to the package body to form a hollow structure; and a bonding member for bonding the package body and the lid-like member to each other. The bonding member is a resin adhesive containing an epoxy resin, a polymerization initiator, and a filling material, and a content of the filling material in the bonding member is 30 wt % to 60 wt %.

### CROSS REFERENCE TO RELATED APPLICATION

This application claims priority under 35 U.S.C. §119 on Patent Application No. 2007-311926 filed in Japan on Dec. 3, 2007, the entire contents of which are hereby incorporated by reference.

### BACKGROUND OF THE INVENTION

1. Field of the Invention

The invention relates to a semiconductor device having a semiconductor element, especially a sensor element or a light receiving/emitting element, mounted in a housing, and a resin adhesive used to manufacture such a semiconductor device.

2. Related Art

Conventionally, in semiconductor devices in which a semiconductor element, such as a semiconductor laser element and an LED (light emitting diode) formed by a light receiving/emitting element or a light emitting element and a CCD (charge coupled device) and a CMOS (complementary metal oxide semiconductor) formed by a light receiving element, is mounted, the semiconductor element is held in a hollow structure formed by a package body and a transparent lid-like member, and the package body and the lid-like member are bonded to each other by a resin adhesive. Similarly, in semiconductor devices in which a semiconductor element such as sound, pressure, and accelerator sensor elements is mounted, a package body and a lid-like member that covers the package body forms a hollow structure for holding the semiconductor element therein, and the package body and the lid-like member are bonded to each other by a resin adhesive.

Hereinafter, a conventional semiconductor device such as CCD or CMOS having a semiconductor element mounted in a hollow structure will be described.

A semiconductor device such as CCD or CMOS is formed as follows: a semiconductor element having an imaging region and a plurality of bonding pads formed thereon is mounted in a cavity portion formed in a package body, and the package body and a transparent lid-like member are bonded to each other by a resin adhesive so that the lid-like member covers the cavity portion having the semiconductor element mounted therein. In this structure, a semiconductor element is first die-bonded to a die attachment surface in a cavity portion formed in a package body made of a resin such as an epoxy resin or a ceramic material, and connection terminals of the package body and aluminum (Al) electrodes of the semiconductor element are connected to each other by wire bonding. The package body and the transparent lid-like member that covers the cavity portion are then bonded to each other by a resin adhesive. A thermosetting resin or an ultraviolet (UV) curable resin is commonly used as the resin adhesive.

Lenses called on-chip lenses are formed on the surface of the semiconductor element to improve light gathering efficiency. The on-chip lenses are made of an acrylic resin and have very low heat resistance. The on-chip lenses are therefore softened and deformed when heated for a long time. When a resin adhesive used to bond the package body and the lid-like member is heated, it is therefore important to perform the heating for as short time as possible and at as low temperature as possible. Accordingly, a UV curable resin is more commonly used than a thermosetting resin. Moreover, regardless of the presence or absence of the on-chip lenses, a UV curable resin has attracted more attention than a thermosetting resin from the standpoint of the working efficiency.

A cationic UV curable resin containing an epoxy resin, a polymerization initiator, a filling material, and the like is often used as the UV curable resin. Since the adhesion property is regarded as important especially for a glass adhesive used for a CCD, diaryliodonium tetrakis (pentafluorophenyl) borate, which is a polymerization initiator having a high sensitivity to UV irradiation, is used in most cases. Moreover, the UV curable resin has a high ratio of the filing material to the epoxy resin that is an adhesive component for fixing the package body to the lid-like member (a solid content of about 25 wt % (weight percent) or less).

In conventional semiconductor devices such as CCD or CMOS, since on-chip lenses have low heat resistance, the temperature properties are not regarded as important, but only the adhesion property is regarded as important for a resin adhesive used to manufacture the semiconductor devices. However, with improvement in materials of the on-chip lenses, the heat resistance of the on-chip lenses has been improved, and the demand to use semiconductor devices such as CCD and CMOS in a high temperature, high humidity environment has been growing. It has therefore been desired to improve the heat resistance and moisture resistance of semiconductor devices and resin adhesives used to manufacture the semiconductor devices in a high temperature, high humidity environment.

Since a semiconductor element is sealed in a cavity portion formed by a package body and a lid-like member, moisture enclosed in the cavity portion may be condensed on the inside of the lid-like member after the package body and the lid-like member are bonded. Moreover, a gas that is generated when a UV curable resin is cured may cause corrosion of wiring portions of the semiconductor element. In order to solve these problems, it has been proposed to dispose a hygroscopic resin in the cavity portion so that the hygroscopic resin adsorbs the moisture (for example, see Japanese Laid-Open Patent Publication No. 2004-22928, which is hereinafter referred to as Document 1).

In conventional semiconductor devices, however, the adhesion property of the resin adhesive is regarded as important, and the curing property and hygroscopic property of the resin adhesive are not considered. Therefore, when thermal stress is applied in a high temperature, high humidity environment, peeling may occur between the package body and the resin adhesive and between the lid-like member and the resin adhesive.

As the resin adhesive absorbs moisture, the adhesive power is reduced at the interface between the resin adhesive and the bonded member. Peeling occurs when thermal stress is applied to the interface having the reduced adhesive power. Among the components of the resin adhesive, the resin is hygroscopic (the resin adhesive components other than the solid (inorganic material)). A resin adhesive having a higher resin content is therefore more likely to absorb moisture.

When peeling occurs in a semiconductor device having a semiconductor element mounted in a cavity portion formed by a package body and a lid-like member, moisture is more likely to enter the cavity portion through the peeling. The moisture may be condensed on the inside of the transparent lid-like member, resulting in failure of the semiconductor device. Moreover, a compound liberated from a resin adhesive may cause corrosion of metal wiring portions in the cavity portion due to the presence of moisture, thereby causing defective connection.

One of the measures to prevent peeling is to dispose a hygroscopic substance in the cavity portion as described in Document 1. In this case, even if moisture enters the cavity portion formed by the package body and the lid-like member, the hygroscopic substance disposed in the cavity portion adsorbs the moisture, whereby liberation of the compound from the resin adhesive can be suppressed. However, disposing the hygroscopic substance in the package increases the size and cost of the semiconductor device.

### SUMMARY OF THE INVENTION

In order to solve the above conventional problems, it is an object of the invention to obtain a semiconductor device capable of preventing peeling between a package body and a resin adhesive and between a resin adhesive and a lid-like member even when thermal stress is applied in a high temperature, high humidity environment, and a resin adhesive used for the semiconductor device.

In order to achieve the above object, according to the invention, a resin adhesive used to manufacture a semiconductor device contains an epoxy resin, a polymerization initiator, and a filling material, and has a solid content, that is, a filling-material content, of 30 wt % to 60 wt %.

More specifically, a semiconductor device according to the invention includes: a semiconductor element; a package body having the semiconductor element bonded inside thereof and electrically connected to the semiconductor element; a lid-like member covering the semiconductor element, and bonded to the package body to form a hollow structure; and a bonding member for bonding the package body and the lid-like member to each other, wherein the bonding member is a resin adhesive containing an epoxy resin, a polymerization initiator, and a filling material, and a content of the filling material in the bonding member is 30 wt % to 60 wt %.

The semiconductor device of the invention uses the resin adhesive having a higher content of the filling material and a lower content of the resin that absorbs moisture as compare to conventional examples. The resin adhesive is therefore less likely to absorb moisture even when thermal stress is applied in a high temperature, high humidity environment. Peeling can therefore be prevented from occurring between the package body and the resin adhesive and between the lid-like member and the resin adhesive. As a result, a reliable semiconductor device can be obtained.

In the semiconductor device of the invention, the content of the filling material is preferably 40 wt % to 50 wt %.

In this case, the semiconductor device is manufactured by using the resin adhesive having optimal conditions. Peeling can therefore be more prevented from occurring even when thermal stress is applied in a high temperature, high humidity environment.

In the semiconductor device of the invention, the polymerization initiator is preferably an onium compound.

When the polymerization initiator is an onium compound in the semiconductor device of the invention, the onium compound is preferably a sulfonium compound.

When the polymerization initiator is a sulfonium compound in the semiconductor device of the invention, the sulfonium compound preferably contains halogen.

In this case, the resin adhesive has higher elasticity and can therefore absorb stress even when thermal stress is applied. As a result, a reliable semiconductor device can be obtained.

In the semiconductor device of the invention, the package body is preferably a ceramic substrate.

Since the ceramic substrate has low moisture absorptivity, the amount of moisture that enters a cavity portion can be reduced. As a result, a more reliable semiconductor device can be obtained.

In the semiconductor device of the invention, the package body is preferably a resin substrate.

Since the resin substrate is lighter than the ceramic substrate, a lighter semiconductor device can be obtained. This can contribute to weight reduction of mobile devices having the semiconductor device of the invention mounted therein.

In the semiconductor device of the invention, the semiconductor element is preferably a sound sensor element, a pressure sensor element, an acceleration sensor element, a semiconductor laser element, a light emitting diode, a solid-state imaging element, or a photodiode.

A resin adhesive according to the invention contains an epoxy resin, a polymerization initiator which is an onium compound, and a filling material, wherein a content of the filling material is 30 wt % to 60 wt %.

The resin adhesive of the invention has a higher content of the filling material as compared to conventional resin adhesives. Since the resin adhesive of the invention has a lower content of the resin that is likely to absorb moisture, moisture absorption of the resin adhesive can be suppressed.

In the resin adhesive of the invention, the onium compound is preferably a sulfonium compound containing halogen.

As has been described above, according to the semiconductor device of the invention and the resin adhesive used to manufacture the semiconductor device, peeling between the package body and the resin adhesive and between the resin adhesive and the lid-like member can be suppressed even when thermal stress is applied in a high temperature, high humidity environment. A reliable semiconductor device and a resin adhesive used to manufacture such a semiconductor device can therefore be implemented.

### BRIEF DESCRIPTION OF THE DRAWINGS

FIG. 1A is a plan view of a semiconductor device according to a first embodiment of the invention, and FIG. 1B is a cross-sectional view taken along line Ib-Ib in FIG. 1A;

FIGS. 2A, 2B, 2C, 2D, and 2E are cross-sectional views sequentially illustrating the steps of a manufacturing method of a semiconductor device according to the first embodiment of the invention;

FIG. 3A is a plan view of a semiconductor device according to a second embodiment of the invention, and FIG. 3B is a cross-sectional view taken along line IIIb-IIIb in FIG. 3A; and

FIGS. 4A, 4B, 4C, 4D, and 4E are cross-sectional views sequentially illustrating the steps of a manufacturing method of a semiconductor device according to the second embodiment of the invention.

### DETAILED DESCRIPTION OF THE PREFERRED EMBODIMENTS

Embodiments of the invention will now be described with reference to the accompanying drawings. In the figures, the thicknesses and lengths of components depicted are different from actual ones for convenience of illustration. The same is applied to the number of electrodes and terminals of the components. Moreover, materials for the components are not limited to those described below.

### First Embodiment

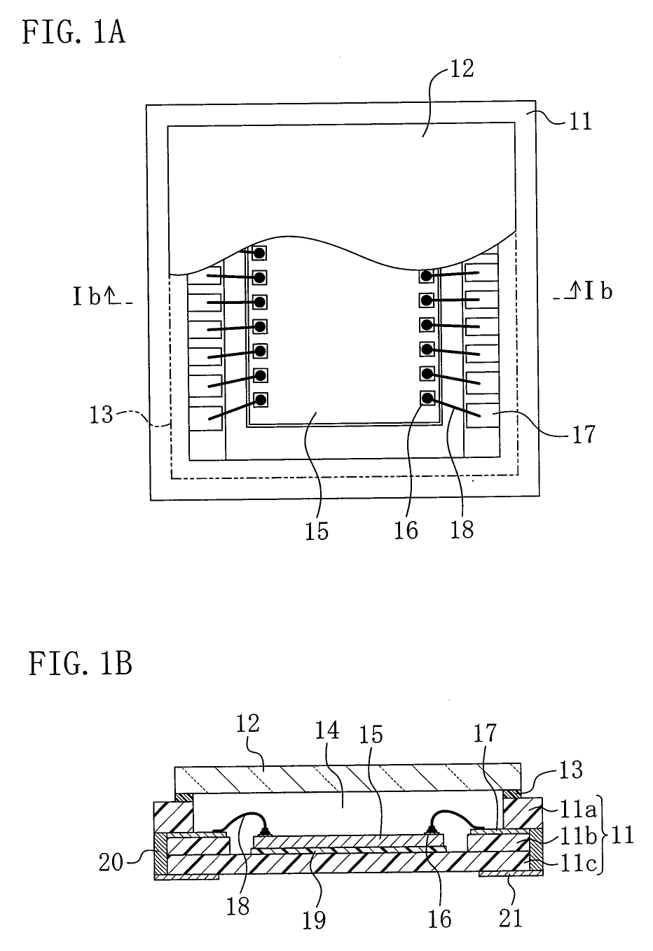

FIGS. 1A and 1B show a semiconductor device according to a first embodiment of the invention. FIG. 1A shows a planar structure and FIG. 1B shows a cross-sectional structure taken along line Ib-Ib in FIG. 1A. In the first embodiment, a substrate of the semiconductor device is a ceramic multilayer substrate 11.

As shown in FIGS. 1A and 1B, in the semiconductor device of the first embodiment, a transparent lid-like member 12 is bonded to the ceramic multilayer substrate 11, i.e., a package body, with a resin adhesive 13 so that the ceramic multilayer substrate 11 and the lid-like member 12 form a cavity portion 14. A semiconductor element 15 disposed in the cavity portion 14 has a plurality of Al (aluminum) electrodes 16 formed on the top surface thereof. The ceramic multilayer substrate 11 has a plurality of connection terminals 17 formed thereon. The Al electrodes 16 and the connection terminals 17 are electrically connected to each other through Au (gold) wires 18.

The ceramic multilayer substrate 11 is formed by three layers: an upper layer 11a, an intermediate layer 11b, and a lower layer 11c. The upper layer 11a and the intermediate layer 11b are frame-shaped when viewed two-dimensionally. The cavity portion 14 is therefore formed by bonding the lid-like member 12 to the upper layer 11a. The semiconductor element 15 is disposed on the top surface of the lower layer 11c within the cavity 14 with a die bonding material 19. The connection terminals 17 formed between the upper layer 11a and the intermediate layer 11b are electrically connected to the Al electrodes 16 formed on the top surface of the semiconductor element 15. The connection terminals 17 are also electrically connected to external side electrodes 20 formed on the side surface of the ceramic multilayer substrate 11 and external bottom electrodes 21 formed on the bottom surface of the lower layer 11c. The external side electrodes 20 are in the form of longitudinal halves of through holes extending through the intermediate layer 11b and the lower layer 11c of the ceramic multilayer substrate 11 from the top surface to the bottom surface thereof. In other words, the external side electrodes 20 have a semicircular shape when viewed two-dimensionally.

Such a package form is called an LCC (leadless chip carrier) structure, which is one of package forms that are excellent for reduction in size and thickness.

The resin adhesive 13 of the first embodiment will now be described.

The resin adhesive 13 of the first embodiment is a UV curable resin formed by an epoxy resin, a polymerization initiator, and a filling material in order to avoid thermal damage to the semiconductor element 15, especially to on-chip lenses formed on an imaging region on the surface of the semiconductor element 15. The use of the UV curable resin as the resin adhesive 13 enables reduction in curing time as compared to the case where a thermosetting resin is used. As a result, the manufacturing tact time can be reduced.

Desirable specific examples of the epoxy resin contained in the resin adhesive 13 include bisphenol epoxy resins, novolac epoxy resins, and biphenyl epoxy resins. Among the bisphenol epoxy resins, a bisphenol A epoxy resin, a bisphenol S epoxy resin, or a bisphenol F epoxy resin is most commonly used. An epoxy resin that is in the liquid state at room temperature is preferably used.

The polymerization initiator of the resin adhesive 13 is an onium compound. Examples of an onium compound cation include sulfonium, sulfosonium, selenonium, phosphonium, and ammonium. For example, an onium compound anion may be a halogen-containing compound.

The filling material of the resin adhesive 13 may be an inorganic filler such as aluminum oxide (Al₂O₃), magnesium oxide (MgO), boron nitride (BN), aluminum nitride (AlN), or silicon oxide (SiO₂).

TABLE 1

| | | Experimental | Experimental | Experimental | Experimental |
|---|---|---|---|---|---|
| Composition | | example 1 | example 2 | example 3 | example 4 |
| Resin content [wt %] | | 75-80 | 60-70 | 50-60 | 40-50 |
| Filling material content [wt %] | | 20-25 | 30-40 | 40-50 | 50-60 |
| Number of defective | 168 h | 24/24 | 0/24 | 0/24 | 0/24 |
| samples generated | 500 h | — | 0/24 | 0/24 | 0/24 |
| in high temperature/ | 1,000 h | — | 0/24 | 0/24 | 0/24 |
| high humidity test | 1,200 h | — | 2/24 | 0/24 | 6/24 |

Table 1 shows the result of a high temperature/high humidity test performed on the resin adhesives 13 having various contents of an epoxy resin, a polymerization initiator, and a filling material.

Semiconductor devices were manufactured by using resin adhesives with a resin content (the total amount of an epoxy resin and a polymerization initiator) and a content of a filling material including a filler, talc, and an ion adsorbent adjusted to various values (wt %). The high temperature/high humidity test was performed for 168 hours, 500 hours, 1,000 hours, and 1,200 hours on the semiconductor devices thus manufactured. 24 samples were used for each test condition, and the number of defective samples generated in each test condition is shown in the table.

Note that, as a preprocessing of the test, samples were stored in a thermo-hygrostat bath having a temperature of 30° C. and a humidity of 70% for 96 hours and then heat treated at 220° C. After the preprocessing, the samples were stored in an environment having a higher temperature and a higher humidity than in the preprocessing for a predetermined time. The samples were then examined to see if they were defective or not.

The result of Table 1 shows that no defective sample was generated even after 1,000 hours or more under the high temperature/high humidity conditions when the content of the filling material (that is, the solid content) in the resin adhesive 13 was 30 wt % to 60 wt %. It was also found that no defective sample was generated even after a longer period of time under the high temperature/high humidity conditions when the solid content of the resin adhesive 13 was 40 wt % to 50 wt %.

Hereinafter, each component of the semiconductor device of the first embodiment will be described.

The ceramic multilayer substrate 11 is formed by, for example, three ceramic insulating layers. For example, the ceramic material may be a sintered body of alumina, aluminum nitride, or the like, or a sintered body of glass-added ceramic material obtained by low-temperature baking. Alternatively, a resin material having ceramic powder added thereto may be molded into the substrate. In order to retain the high heat resistance of the ceramic multilayer substrate 11, it is preferable to use the sintered body of ceramic material such as alumina.

The connection terminals 17, the external side electrodes 20, and the external bottom electrodes 21 formed on the ceramic multilayer substrate 11 can be obtained by, for example, forming a Cu (copper) plating layer by a combined use of electroless copper plating and electrolytic copper plating and patterning the copper plating layer into a desired shape by etching. Alternatively, the connection terminals 17, the external side electrodes 20, and the external bottom electrodes 21 may be formed by a printing method using, for example, a Cu paste or a silver (Ag) paste. Although not shown in the figures, it is preferable to form a thin gold film on the surfaces of the connection terminals 17, the external side electrodes 20, and the external bottom electrodes 21. The thin gold film is preferably provided by, for example, forming a nickel plating layer on the copper plating film or thick copper wires and forming a thin gold film thereon by gold plating. This improves bondability of the Au wires 18 to the connection terminals 17 and also improves solder wettability of the external side electrodes 17 and the external bottom electrodes 21, thereby enhancing the reliability of the joints.

The lid-like member 12 is preferably a light transmitting member having a transmittance of at least 70%, preferably 80% or more, and more preferably 90% or more. More specifically, a glass plate is commonly used as the lid-like member 12.

For example, the die bonding material 19 may be a thermosetting resin paste such as an epoxy resin or a polyimide resin. Instead of the thermosetting resin paste, a tape-like adhesive may be used as the die bonding material 19. When high heat resistance is desired, it is preferable to use, for example, a resin paste with a metallic filler such as Ag dispersed therein.

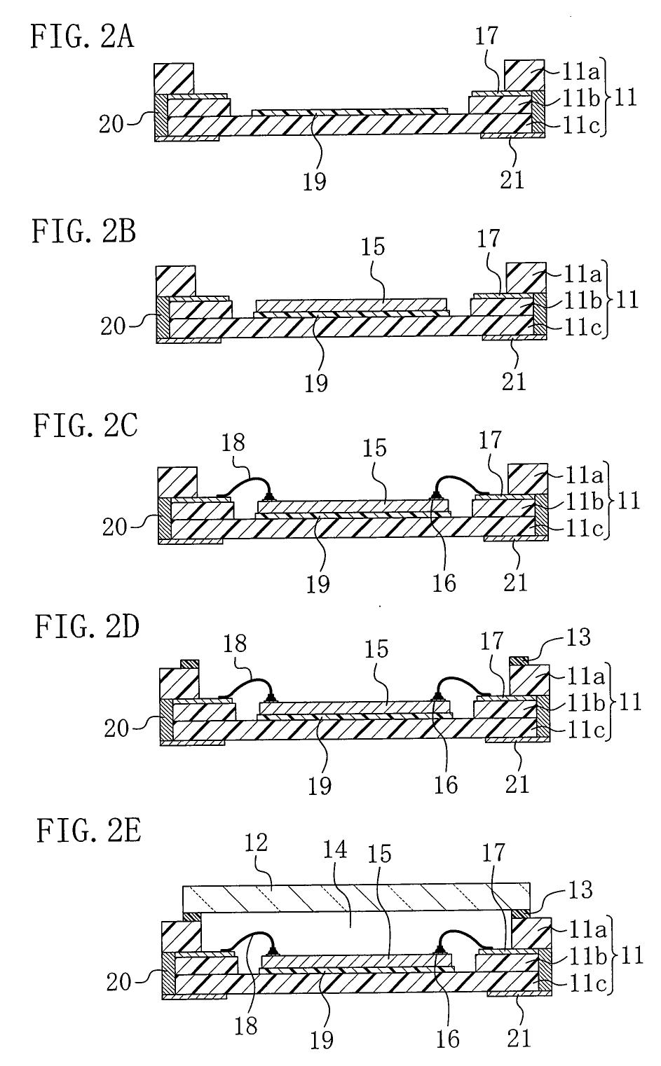

Hereinafter, a manufacturing method of a semiconductor device according to the first embodiment will be described with reference to FIGS. 2A through 2E.

FIGS. 2A through 2E show cross-sectional structures sequentially illustrating the steps of the manufacturing method of a semiconductor device according to the first embodiment.

As shown in FIG. 2A, a ceramic multilayer substrate 11 is prepared. The ceramic multilayer substrate 11 is formed by an upper layer 11a, an intermediate layer 11b, and a lower layer 11c, and has connection terminals 17, external side electrodes 20, and external bottom electrodes 21 formed thereon. A die bonding material 19 is applied to a recess of the ceramic multilayer substrate 11 by using, for example, a dispenser in order to enable mounting of a semiconductor element thereon. The dispenser for applying the die bonding material 19 may have a single nozzle or multiple nozzles. Instead of using the dispenser, the die bonding material 19 may be supplied by a transfer method.

For example, the die bonding material 19 may be a thermosetting paste containing a thermosetting resin such as an epoxy resin or a polyimide resin as a main component. The epoxy resin may desirably be bisphenol epoxy resins, novolac epoxy resins, or biphenyl epoxy resins. Among the bisphenol epoxy resins, for example, a bisphenol A epoxy resin, a bisphenol S epoxy resin, or a bisphenol F epoxy resin is most commonly used. An epoxy resin that is in the liquid state at room temperature is preferably used. When high heat resistance is desired, it is preferable to use a resin paste with a metallic filler such as Ag dispersed therein. A tape-like adhesive may be used instead of the thermosetting resin paste. The tape-like adhesive is bonded to the rear surface of a wafer before dicing into individual semiconductor elements. The tape-like adhesive is thus simultaneously cut in the dicing process, whereby individual semiconductor elements having the tape-like adhesive on the rear surface thereof can be obtained.

As shown in FIG. 2B, a semiconductor element 15 is placed on the die bonding material 19 in the recess of the ceramic multilayer substrate 11. The resultant substrate is stored in an environment of 120° C. to 170° C. for two hours by using a thermosetting oven or the like in order to thermally cure the die bonding material 19. It is desirable to perform this thermal curing process in a nitrogen atmosphere in order to prevent surface oxidation of Al electrodes 16 provided on the top surface of the semiconductor element 15.

As shown in FIG. 2C, the Al electrodes 16 of the semiconductor element 15 are then connected to the connection terminals 17 of the ceramic multilayer substrate 11 through Au wires 18 by using, for example, a ball bonding method.

The connection between the Al electrodes 16 and the connection terminals 17 may be achieved by a wedge bonding method instead of the ball bonding method. The Au wires 18 may be replaced with Al or Cu wires. Any connection method may be used as long as the Al electrodes 16 of the semiconductor element 15 and the connection terminals 17 of the ceramic multilayer substrate 11 are electrically connected to each other through wires. The Al electrodes 16 of the semiconductor element 15, the Au wires 18, the connection terminals 17, the external side electrodes 20, and the external bottom electrodes 21 are thus electrically connected to each other.

As shown in FIG. 2D, a resin adhesive 13 is then applied to the upper layer 11a of the ceramic multilayer substrate 11 by using, for example, a dispenser.

As shown in FIG. 2E, a lid-like member 12 made of a transparent material is placed on the ceramic multilayer substrate 11 with the resin adhesive 13 applied thereon. The ceramic multilayer substrate 11 and the lid-like member 12 thus form a cavity portion 12 having the semiconductor element 15 disposed therein. The top surface of the lid-like member 12 is then irradiated with UV light in order to cure the resin adhesive 13. The UV irradiation initiates polymerization of the resin adhesive 13 and thus cures the resin adhesive 13, whereby the ceramic multilayer substrate 11 and the lid-like member 12 are bonded to each other. It is desirable that the UV light has a wavelength of 300 nm or higher and illumination of 200 mW or higher.

In order to completely cure the resin adhesive 13, the substrate is stored in an environment of 120° C. for four hours after the UV irradiation. The ceramic multilayer substrate 11 and the lid-like member 12 are thus firmly bonded to each other by the resin adhesive 13 to form the cavity portion 14. A semiconductor device having the semiconductor element 15 mounted in the cavity portion 14 can be thus be obtained.

According to the semiconductor device of the first embodiment, the ceramic multilayer substrate as a package body and the lid-like member are bonded to each other by using a resin adhesive having a lower content of resin that is likely to absorb moisture and a higher solid content as compared to conventional examples. As a result, peeling between the resin adhesive material and the ceramic multilayer substrate and between the resin adhesive and the lid-like member, that is, interfacial peeling between the resin adhesive material and the bonded member, can be suppressed even when thermal stress is applied in a high temperature, high humidity environment.

Note that, in the first embodiment, the ceramic multilayer substrate is formed by three ceramic insulating layers. However, the invention is not limited to three layers. The ceramic multilayer substrate may be formed by any number of layers as long as a cavity portion is formed by the substrate and the lid-like member. Although the external side electrodes and the external bottom electrodes are provided in the first embodiment, one of the external side electrodes and the external bottom electrodes may be omitted as long as the semiconductor element can be electrically connected to external terminals. Accordingly, the lid-like member may be formed so as to cover the side surface of the semiconductor device.

It is assumed in the first embodiment that the semiconductor element is a light receiving element. Instead of light receiving elements, however, other semiconductor elements may be used such as a semiconductor laser element, a light emitting diode (LED), a solid-state imaging element, a photodiode, a sound sensor element, a pressure sensor element, or an acceleration sensor element. In the case where a non-light-receiving/emitting element such as a sound sensor element, a pressure sensor element, or an acceleration sensor element is used as the semiconductor element, the lid-like member need not be a light transmitting member.

### Second Embodiment

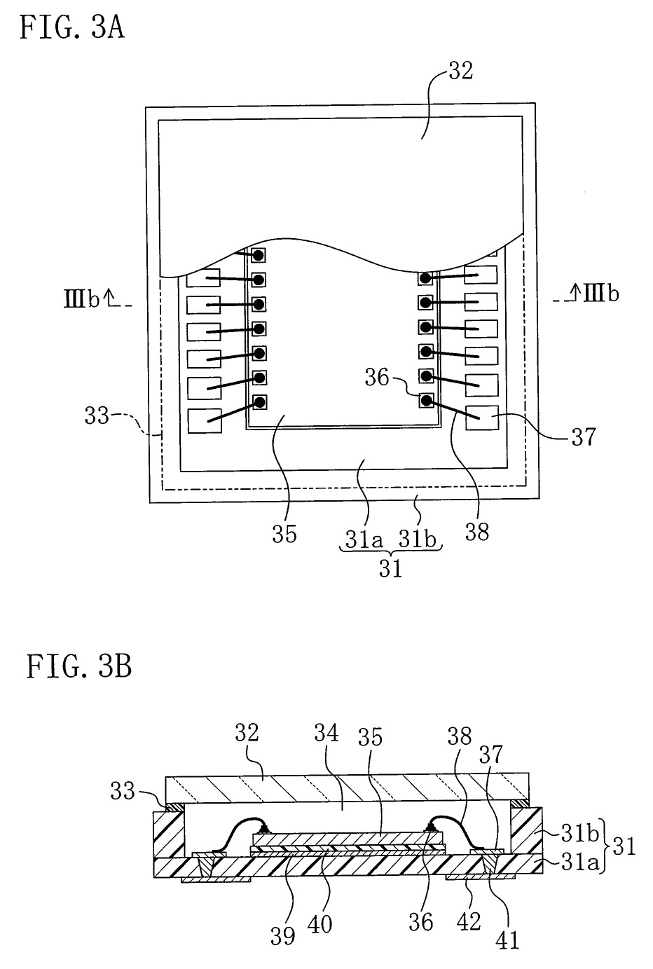

FIGS. 3A and 3B show a semiconductor device according to a second embodiment of the invention. FIG. 3A shows a planar structure and FIG. 3B shows a cross-sectional structure taken along line IIIb-IIIb in FIG. 3A. In the second embodiment, a substrate of the semiconductor device is a resin substrate 31.

As shown in FIGS. 3A and 3B, in the semiconductor device of the second embodiment, the resin substrate 31 as a package body is formed by a BT (bismaleimide triazine) resin substrate 31a and a resin rib 31b formed on the periphery of the substrate 31a. A transparent lid-like member 32 is bonded to the top surface of the rib 31b with a resin adhesive 33 so that a cavity portion 34 is formed between the substrate 31a and the lid-like member 32. A semiconductor element 35 is placed on the top surface of the substrate 31a within the cavity portion 34. Al electrodes 36 formed on the top surface of the semiconductor element 35 and connection terminals 37 formed on the resin substrate 31 are electrically connected to each other through Au wires 38. An element mounting region is defined on the top surface of the substrate 31a. A die pattern 39 is formed in the element mounting region and the semiconductor element 35 is bonded on the die pattern 39 by using a die bonding material 40. The die pattern 39 is electrically connected to the semiconductor element 35. Through conductors 41 are formed so as to extend through the substrate 31a from the top surface to the bottom surface thereof. The connection terminals 37 and external connection terminals 42 formed on the bottom surface of the substrate 31a are electrically connected to each other by the through conductors 41. Although not shown in the figures, the connection terminals 37 are formed on the entire peripheral region of the element mounting region formed in the middle of the top surface of the substrate 31a.

Hereinafter, each component of the semiconductor device of the second embodiment will be described.

Like the resin adhesive 13 of the first embodiment, a UV curable resin formed by an epoxy resin, a polymerization initiator, and a filling material is used as the resin adhesive 33 in order to avoid thermal damage to the semiconductor element 35, especially to on-chip lenses formed on an imaging region on the surface of the semiconductor element 35. The content of the filling material, that is, the solid content, in the resin adhesive 33 is preferably 30 wt % to 60 wt %, and more preferably, 40 wt % to 50 wt %. The use of such a resin adhesive 33 to bond the package body to the lid-like member enables implementation of a semiconductor device that does not become defective even after 1,000 hours or more under high temperature, high humidity conditions. Moreover, as in the first embodiment, the use of the UV curable resin as the resin adhesive 33 enables reduction in curing time as compared to the case where a thermosetting resin is used. As a result, the manufacturing tact time can be reduced.

Instead of the BT resin, various resin substrates may be used as the substrate 31a of the resin substrate 31. For example, a resin substrate may be prepared using a base material formed by immersing an organic fiber such as a glass fiber or Kevlar (registered trademark) with an epoxy resin, a phenol resin, a polyimide resin, or the like and curing the resin. Although not shown in the figures, it is preferable to form a thin gold film on the surfaces of the connection terminals 37, the die pattern 39, the through conductors 41, and the external connection terminals 42 of the substrate 31a. The thin gold film is preferably provided by forming a nickel plating layer on the copper pattern and then forming a thin gold film thereon by gold plating. This improves bondability of the Au wires 38 to the connection terminals 37 and also improves solder wettability of the die pattern 39, the through conductors 41, and the external connection terminals 42, thereby enhancing the reliability of the joints.

The rib 31b of the resin substrate 31 is a frame-shaped member and can be easily obtained by molding a resin, such as a liquid crystal polymer, polyphenylene sulfide, or polyethylene terephthalate.

The lid-like member 32 is preferably a light transmitting member having a transmittance of at least 70%, preferably 80% or more, and more preferably 90% or more. More specifically, a glass plate is commonly used as the lid-like member 32.

For example, the die bonding material 40 may be a thermosetting resin paste such as an epoxy resin or a polyimide resin. Instead of the thermosetting resin paste, a tape-like adhesive may be used as the die bonding material 40. When high heat resistance is desired, it is preferable to use, for example, a resin paste with a metallic filler such as Ag dispersed therein.

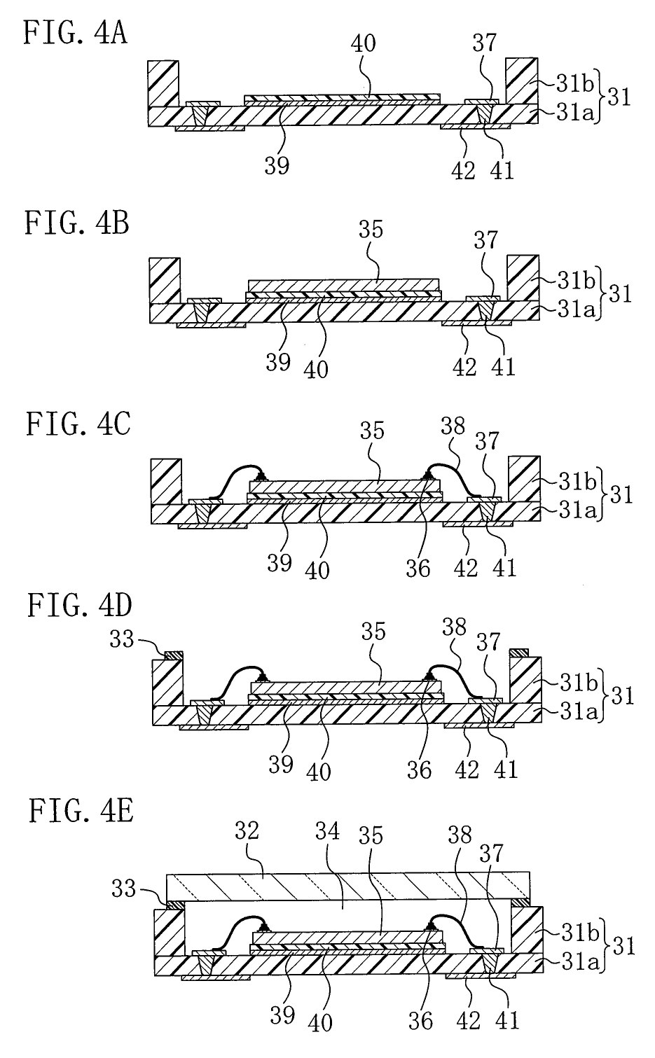

Hereinafter, a manufacturing method of a semiconductor device according to the second embodiment will be described with reference to FIGS. 4A through 4E.

FIGS. 4A through 4E show cross-sectional structures sequentially illustrating the steps of the manufacturing method of a semiconductor device according to the first embodiment.

As shown in FIG. 4A, a resin substrate 31 formed by a substrate 31a and a frame-shaped rib 31b is prepared. For example, the resin substrate 31 may be formed as follows: a copper foil having a thickness of about 18 μm is applied to both surfaces of a BT resin substrate having a thickness of about 0.2 mm, and through holes are then formed so as to extend from the top surface to the bottom surface of the substrate. After the through holes are formed, a copper plating layer is formed on both surfaces of the substrate by electroless copper plating and electrolytic copper plating. Since the copper plating layer is formed also on the inner surfaces of the through holes, through conductors 41 are formed. Thereafter, the substrate 31a having connection terminals 37 and a die pattern 39 formed on the top surface thereof and external connection terminals 42 formed on the bottom surface thereof is formed by a photolithography process and an etching process. A frame-shaped rib 31b is then bonded to the substrate 31a thus formed by using a thermosetting resin adhesive. The resin substrate 31 is thus formed. Alternatively, a sheet comprised of a plurality of substrates 31a may be prepared. In this case, the rib 31b may be formed on the sheet by transfer molding using a biphenyl epoxy resin, a phenol novolac epoxy resin, or the like, followed by dicing the sheet into individual resin substrates 31 each formed by the substrate 31a and the rib 31b.

A die bonding material 40 is applied onto the die pattern 39 of the prepared resin substrate 31 by using, for example, a dispenser. The dispenser for applying the die bonding material 40 may have a single nozzle or multiple nozzles. Instead of using the dispenser, the die bonding material 40 may be supplied by a transfer method.

For example, the die bonding material 40 may be a thermosetting paste containing a thermosetting resin such as an epoxy resin or a polyimide resin as a main component. The epoxy resin may desirably be bisphenol epoxy resins, novolac epoxy resins, or biphenyl epoxy resins. Among the bisphenol epoxy resins, for example, a bisphenol A epoxy resin, a bisphenol S epoxy resin, or a bisphenol F epoxy resin is most commonly used. An epoxy resin that is in the liquid state at room temperature is preferably used. When high heat resistance is desired, it is preferable to use, for example, a resin paste with a metallic filler such as Ag dispersed therein. A tape-like adhesive may be used instead of the thermosetting resin paste. The tape-like adhesive is bonded to the rear surface of a wafer before dicing into individual semiconductor elements. The tape-like adhesive is thus simultaneously cut in the dicing process, whereby individual semiconductor elements having the tape-like adhesive on the rear surface thereof can be obtained.

As shown in FIG. 4B, a semiconductor element 35 is placed on the die bonding material 40 of the resin substrate 31. The resultant substrate is stored in an environment of 120° C. to 170° C. for two hours by using a thermosetting oven or the like in order to thermally cure the die bonding material 40. It is desirable to perform this thermal curing process in a nitrogen atmosphere in order to prevent surface oxidation of Al electrodes 36 provided on the top surface of the semiconductor element 35.

As shown in FIG. 4C, the Al electrodes 36 of the semiconductor element 35 are then connected to the connection terminals 37 of the resin substrate 31 through Au wires 38 by using, for example, a ball bonding method.

The connection between the Al electrodes 36 and the connection terminals 37 may be achieved by a wedge bonding method instead of the ball bonding method. The Au wires 38 may be replaced with Al or Cu wires. Any connection method may be used as long as the Al electrodes 36 of the semiconductor element 35 and the connection terminals 37 of the resin substrate 31 are electrically connected to each other through wires. The Al electrodes 36 of the semiconductor element 35, the Au wires 38, the connection terminals 37, the through conductors 41, and the external connection terminals 42 are thus electrically connected to each other.

As shown in FIG. 4D, a resin adhesive 33 is then applied onto the rib 31b by using, for example, a dispenser.

As shown in FIG. 4E, a lid-like member 32 made of a transparent material is placed on the resin substrate 31 with the resin adhesive 33 applied thereon. The resin substrate 31 and the lid-like member 32 thus form a cavity portion 34 having the semiconductor element 35 disposed therein. Preheating is then performed at a low temperature to temporarily fix the lid-like member 32 to the resin substrate 31. The top surface of the lid-like member 32 is then irradiated with UV light. The UV irradiation initiates polymerization of the resin adhesive 33 and thus cures the resin adhesive 33, whereby the resin substrate 31 and the lid-like member 32 are bonded to each other. It is desirable that the UV light has a wavelength of 300 nm or higher and illumination of 200 mW or higher. A semiconductor device having the semiconductor element 35 mounted in the cavity portion 34 formed by bonding the resin substrate 31 and the lid-like member 32 to each other by the resin adhesive 33 can thus be formed.

According to the semiconductor device of the second embodiment, the resin substrate as a package body and the lid-like member are bonded to each other by using a resin adhesive having a lower content of resin that is likely to absorb moisture and a higher solid content as compared to conventional examples. As a result, peeling between the resin adhesive material and the resin substrate and between the resin adhesive and the lid-like member, that is, interfacial peeling between the resin adhesive material and the bonded member, can be suppressed even when thermal stress is applied in a high temperature, high humidity environment.

Note that, in the second embodiment, a recess is formed in the resin substrate 31 by bonding the frame-shaped rib 31b to the substrate 31a. However, a resin substrate 31 formed only by a substrate 31a having a recess may be used. The resin substrate may be replaced with a ceramic substrate.

As in the first embodiment, it is assumed in the second embodiment that the semiconductor element is a light receiving element. Instead of light receiving elements, however, other semiconductor elements may be used such as a semiconductor laser element, an LED, a solid-state imaging element, a photodiode, a sound sensor element, a pressure sensor element, or an acceleration sensor element. In the case where a non-light receiving/emitting element such as a sound sensor element, a pressure sensor element, or an acceleration sensor element is used as the semiconductor element, the lid-like member need not be a light transmitting member.

As has been described above, the semiconductor device according to the invention and the resin adhesive used to manufacture the semiconductor device are useful as a semiconductor device capable of suppressing peeling between a resin adhesive and a bonded member even when thermal stress is applied in a high temperature, high humidity environment, and having a semiconductor element, especially a sensor element or a light receiving/emitting element, mounted within a housing, and a resin adhesive used to manufacture the semiconductor device, and the like.

What is claimed is:

1. A semiconductor device, comprising:
a semiconductor element;
a package body having the semiconductor element bonded inside thereof and electrically connected to the semiconductor element;
a lid-like member covering the semiconductor element, and bonded to the package body to form a hollow structure; and
a bonding member for bonding the package body and the lid-like member to each other, wherein the bonding member is a resin adhesive containing an epoxy resin, a polymerization initiator, and a filling material, and a content of the filling material in the bonding member is 30 wt % to 60 wt %.

2. The semiconductor device according to claim 1, wherein the content of the filling material is 40 wt % to 50 wt %.

3. The semiconductor device according to claim 1, wherein the polymerization initiator is an onium compound.

4. The semiconductor device according to claim 3, wherein the onium compound is a sulfonium compound.

5. The semiconductor device according to claim 4, wherein the sulfonium compound contains halogen.

6. The semiconductor device according to claim 1, wherein the package body is a ceramic substrate.

7. The semiconductor device according to claim 1, wherein the package body is a resin substrate.

8. The semiconductor device according to claim 1, wherein the semiconductor element is a sound sensor element, a pressure sensor element, an acceleration sensor element, a semiconductor laser element, a light emitting diode, a solid-state imaging element, or a photodiode.

9. A resin adhesive containing an epoxy resin, a polymerization initiator which is an onium compound, and a filling material, wherein a content of the filling material is 30 wt % to 60 wt %.

10. The resin adhesive according to claim 9, wherein the onium compound is a sulfonium compound containing halogen.
